(19) United States
(12) Patent Application Publication
(10) Pub. No.: US 2008/0204366 A1
(43) Pub. Date: Aug. 28, 2008

(54) BROAD COLOR GAMUT DISPLAY

(76) Inventors: Paul J. Kane, Rochester, NY (US); Ronald S. Cok, Rochester, NY (US)

Correspondence Address: Frank Pincelli;Patent Legal Staff, Eastman Kodak Company, 343 State Street, Rochester, NY, 14650-2201, US

(21) Appl. No.: 11/678,782

(22) Filed: Feb. 26, 2007

(51) Int. Cl. G09G 3/06

(52) U.S. Cl. 345/44

(57) ABSTRACT

A method of making a color electroluminescent display device that includes determining a number of light emitting elements per pixel; and providing a substantially continually variable wavelength set of inorganic light-emitters having a spectral width. The same number of different inorganic light emitters is selected to emit light at the same determined number of different wavelengths and that provide the maximum color gamut area within a perceptually uniform two-dimensional color space. The color electroluminescent display device is formed having the same determined number of light emitting elements per pixel, wherein the light emitting elements in each pixel employ the same determined number of different inorganic light emitters.

### FIELD OF THE INVENTION

The present invention relates to a color display composed of inorganic light emitting diode devices that include light emitting layers having quantum dots. In particular, the present invention provides one or more methods for improving the color gamut of such displays.

### BACKGROUND OF THE INVENTION

Semiconductor light emitting diode (LED) devices have been made since the early 1960's and currently are manufactured for usage in a wide range of consumer and commercial applications. The layers comprising the LEDs are based on crystalline semiconductor materials that require ultra-high vacuum techniques for their growth, such as, molecular organic chemical vapor deposition. In addition, the layers typically need to be grown on nearly lattice-matched substrates in order to form defect-free layers. These crystalline-based inorganic LEDs have the advantages of high brightness (due to layers with high conductivities), long lifetimes, good environmental stability, and good external quantum efficiencies. The usage of crystalline semiconductor layers that results in all of these advantages, also leads to a number of disadvantages: for example, high manufacturing costs, difficulty in combining multi-color output from the same chip, and the need for costly, rigid substrates.

In the mid 1980's, organic light emitting diodes (OLED) were invented (Tang et al, Applied Physics Letter 51, 913 (1987)) based on the usage of small molecular weight molecules. In the early 1990's, polymeric LEDs were invented (Burroughes et al., Nature 347, 539 (1990)). In the ensuing 15 years organic based LED displays have been brought out into the marketplace and there have been great improvements in device lifetime, efficiency, and brightness. For example, devices containing phosphorescent emitters have external quantum efficiencies as high as 19%; whereas, device lifetimes are routinely reported at many tens of thousands of hours. In comparison to crystalline-based inorganic LEDs, OLEDs have much reduced brightness (mainly due to small carrier mobilities), shorter lifetimes, and require expensive encapsulation for device operation. On the other hand, OLEDs enjoy the benefits of potentially lower manufacturing cost, the ability to emit multi-colors from the same device, and the promise of flexible displays, if the encapsulation of the OLED can be resolved.

To improve the performance of OLEDs, in the later 1990's devices containing mixed emitters of organics and quantum dots were introduced (Matoussi et al., Journal of Applied Physics 83, 7965 (1998)). The virtue of adding quantum dots to the emitter layers is that the color gamut of the device could be enhanced; red, green, and blue emission could be obtained by simply varying the quantum dot particle size; and the manufacturing cost could be reduced. Because of problems such as aggregation of the quantum dots in the emitter layer, the efficiency of these devices was rather low in comparison with typical OLED devices. A mainly all-inorganic quantum dot LED (QD-LED) was constructed (Mueller et al., Nano Letters 5, 1039 (2005)) by sandwiching a monolayer thick core/shell CdSe/ZnS quantum dot layer between vacuum deposited n- and p-GaN layers. The resulting device had a poor external quantum efficiency of 0.001 to 0.01%. Most recently, in copending application Docket Number 91064, a QD-LED device is described whose emitter layer is formed from inorganic quantum dots, where the inorganic emitter layer is simultaneously conductive and light emissive. In addition, the diode device is formed via low-cost deposition processes.

One of the predominant attributes of quantum dot technology is the ability to control the wavelength of emission, simply by controlling the size of the quantum dot. Quantum dot technology provides the opportunity to relatively easily design and synthesize the emissive layer in these devices to provide any desired peak wavelength, as discussed in a paper by Bulovic and Bawendi, entitled “Quantum Dot Light Emitting Devices for Pixelated Full Color Displays” (Proceedings of the 1996 Society for Information Display Conference). Differently sized quantum dots may be formed and each differently sized quantum dot will emit light at a different peak wavelength, while using differently sized dots made of the same semiconductor material. Therefore the dominant or peak wavelength is said to be substantially continuously variable. This is in contrast to the choice of peak wavelength in traditional LED devices, which employ the same types of semiconductor materials, but require choosing different semiconductor materials to change the emitting wavelengths.

Laser projection displays allow access to a variety of wavelengths. It is known in the technical literature that over 15,000 atomic transitions have been demonstrated to function in laser devices, covering a very broad range of the visible and invisible electromagnetic spectrum. Nevertheless, comparatively few of these wavelengths are available commercially, and although a large number of lasers can be found to cover the visible spectrum (see for example “Handbook of Laser Wavelengths”, M. J. Weber, CRC Press, New York, 1999, Section 6), it is rare to find a single commercially available laser that can be varied to cover the desired color gamut of a display. This increases the cost and complexity of potential display designs based on lasers.

For quantum dot emitters, it is possible to also exercise precise control over the spectral width of the emission peaks. The latter is measured by the full width at half-maximum (FWHM) value, which is the distance between the abscissas at the 50% of maximum spectral power on either side of the peak (seen in FIG. 3). The ability to control peak wavelength and FWHM provides opportunities for creating very colorful light sources that employ single color emitters to create very narrow band and, therefore, highly saturated colors of light emission. This characteristic may be particularly desirable within the area of visual displays, which typically employ a mosaic of three, different colors of light-emitting elements to provide a full-color display.

The need to improve the color rendition of displays is well known, and in particular the desire to increase the saturation, or colorfulness, of pure colors, that is, colors with little or no white content. This is usually understood in the context of a numerical color space such as the CIE x,y chromaticity coordinates. FIG. 1 shows a CIE Chromaticity Diagram on which the chromaticity coordinates x,y of a color emitter or primary can be plotted. The wavelengths of selected monochromatic emitters on the horseshoe-shaped spectrum locus are shown on the CIE plot. The R, G, and B color primaries of the National Television Standard Committee (NTSC) television system standard 8, 10 and 12 are shown on this diagram, and are a frequently used reference against which display systems are compared for performance. The primaries form a triangular color gamut 16 whose vertices are 8, 10 and 12. It is well known that all colors within the gamut's triangular area can be displayed by the primaries, while colors outside the gamut cannot be displayed. Also shown are two other gamuts 18 and 20 associated with representative LCD and OLED display systems, respectively. Note that neither of these display systems matches the gamut area of the NTSC television standard. The OLED system appears to have a larger gamut area 20, and provides better coverage of yellow and green colors, while the LCD gamut 18 appears to provide somewhat better coverage of the blue and purple colors.

Although the x,y chromaticity space is frequently used in the literature to make comparisons between display systems, it has the limitation of not being perceptually uniform. That is, a coordinate difference in one region of the space may not correlate to the same perceived color difference as in another region of the space. It is important to use a perceptually uniform space to avoid distortions that can lead to incorrect design choices. FIG. 2 shows a comparison of the same color gamuts as in FIG. 1, now using the more perceptually uniform CIE u′v′ chromaticity coordinate space. The NTSC primaries 22, 24 and 26 now form the triangular gamut 28, while the LCD and OLED displays form the gamuts 30 and 32, respectively. Seen in this space we note that: (1) The shortfall of the OLED gamut compared to the NTSC in the blue-purple region appears to be more pronounced; (2) All three gamuts are seen to pull more closely to the green-yellow-orange boundary; (3) The deficiency of all three gamuts relative to the blue-purple-red boundary 33 is more obvious; and (4). It appears possible with these display technologies, to approach the monochromatic emitter spectrum locus in a limited region near the yellow-orange boundary, but there are serious shortfalls in every other region of the space. Note also that moving the locations of the primaries in the u′v′ space, i.e. expanding the color gamut, is not trivial for the systems represented in the figures, hence, often requiring substantial research and development effort to develop the necessary materials. Indeed, the positions shown represent some of the best publicly disclosed results to date. As described in the paper by Bulovic and Bawendi and elsewhere, there is a potential for QD-LED materials to become available that will enable the placement of emitters with peak wavelength at selectable points across the visible spectrum and spectral widths (FWHM) on the order of 30 nm. For example, FIG. 3 demonstrates a Gaussian model for a QD-LED spectral emission curve 34 in which the spectral power in arbitrary units (a.u.) is plotted as a function of wavelength in nanometers. The emitter curve has a peak wavelength 36 and a FWHM 38 as shown in the Figure. This presents the problem of the placement of such emitters in the 2-D color space, i.e. given a predetermined number of colors in a display system, for example three (RGB), what values of peak wavelength 36 should be chosen for each color given the FWHM 38, to obtain maximum color gamut? Many suggestions have been made for the optimum placement of the primaries in a three-color system, given the poor fit of a triangle to the shape of the spectrum locus and the resulting loss of coverage. A three-primary set suggested in a paper entitled “Suggested Optimum Primaries and Gamut in Color Imaging” (Thornton, Color & Research Applications 25, 148 (2000)) is selected to match the “prime colors” for the human visual system. As the author suggests, this would establish a system having emitters with peak wavelengths of 450, 530, and 610 nm for the blue, green, and red emissive elements, respectively. This approach supposedly allows a display to provide maximum peak brightness for a given input energy, if it is assumed that the radiant efficiency of each of the emitters is equivalent. FIG. 4 once again shows the NTSC color gamut 40, now along with a new color gamut 42 computed for QD-LED emitters using the Gaussian model of FIG. 3, with peak wavelengths set to Thornton's values and the FWHM at 30 nm, resulting in an RGB primary set with vertices 44, 46 and 48. Unfortunately, this approach does not uniformly expand the color gamut of the display—many colors further beyond the NTSC boundary remain outside the gamut of these primaries, and some colors near the red corner are lost.

Because of the inherent limitation of a three-primary system and its associated triangular gamut, the need for four or more primaries has been appreciated. In WO 2000/11728, Burroughes describes a display device comprising an array of light-emissive pixels, each pixel comprising red, green and blue light emitters and at least one further light emitter for emitting a color to which the human eye is more sensitive than the emission color of at least one of the red and blue emitters. This is taught as a method of power savings, since the extra emitter(s) are inherently brighter to the eye and hence can be driven with less current. Both four and five subpixel solutions are taught. However, it is said to be preferred that the extra emitters lie spectrally between the emission colors of the red and green, or the green and blue, with the result that the extra emitters lie substantially on the triangular gamut of the red, green and blue emitters, and therefore do not act to substantially increase the color gamut. Along similar lines, in WO 2004/0365535 Liedenbaum et. al. discuss an organic electroluminescent display comprising four subpixels, wherein the fourth subpixel has a higher efficiency than the efficiencies of each of the red, green and blue subpixels. Although the result of increased color gamut is recognized, the fourth emitter is chosen and selected on the basis of power efficiency.

In U.S. Pat. No. 6,570,584, Cok et. al. describe a digital color display device, comprising a plurality of pixels, each pixel having four or more subpixels, three of the subpixels being red, green and blue, and at least one of the subpixels producing a color that is outside the gamut defined by the red, green and blue subpixels. The use of the extra subpixels to extend the gamut is taught, however without a method of selecting emitters.

In U.S. Pat. No. 6,6484,75, Roddy et. al. describe a color projection system with increased color gamut, using four lasers or LED arrays as the illumination sources. The authors describe the gamut of such as system in CIE u′v′ chromaticity space, and point out that the color gamut can be maximized as compared to the capability of the human visual system by selecting primaries that are spectrally pure, i.e. substantially monochromatic sources as in a laser. Further work by Roddy et al. in U.S. Pat. No. 6,769,772 extended the color projection system to six lasers or LEDs. Again, no method of selecting emitters is given.

### PROBLEM TO BE SOLVED

Given a predetermined number of light-emitting elements in each pixel of a display, and a continually variable frequency set of inorganic light-emitters having a FWHM (full width half maximum) greater than 5 nm but less than 80 nm, select the predetermined number of different inorganic light emitters that emit light at the predetermined number of different frequencies and provide the maximum area within a perceptually uniform two-dimensional color space.

### SUMMARY OF THE INVENTION

A method of making a color electroluminescent display device that includes determining a number of light emitting elements per pixel; and providing a substantially continually variable wavelength set of inorganic light-emitters having a spectral width. The same number of different inorganic light emitters is selected to emit light at the same determined number of different wavelengths and that provide the maximum color gamut area within a perceptually uniform two-dimensional color space. The color electroluminescent display device is formed having the same determined number of light emitting elements per pixel, wherein the light emitting elements in each pixel employ the same determined number of different inorganic light emitters.

### ADVANTAGES

The display device will have an improved color gamut.

### BRIEF DESCRIPTION OF THE DRAWINGS

FIG. 1 shows a CIE xy chromaticity diagram illustrating the NTSC color gamut along with LCD and OLED color gamuts known in the art;

FIG. 2 shows a CIE u′v′ chromaticity diagram illustrating the NTSC color gamut along with LCD and OLED color gamuts known in the art;

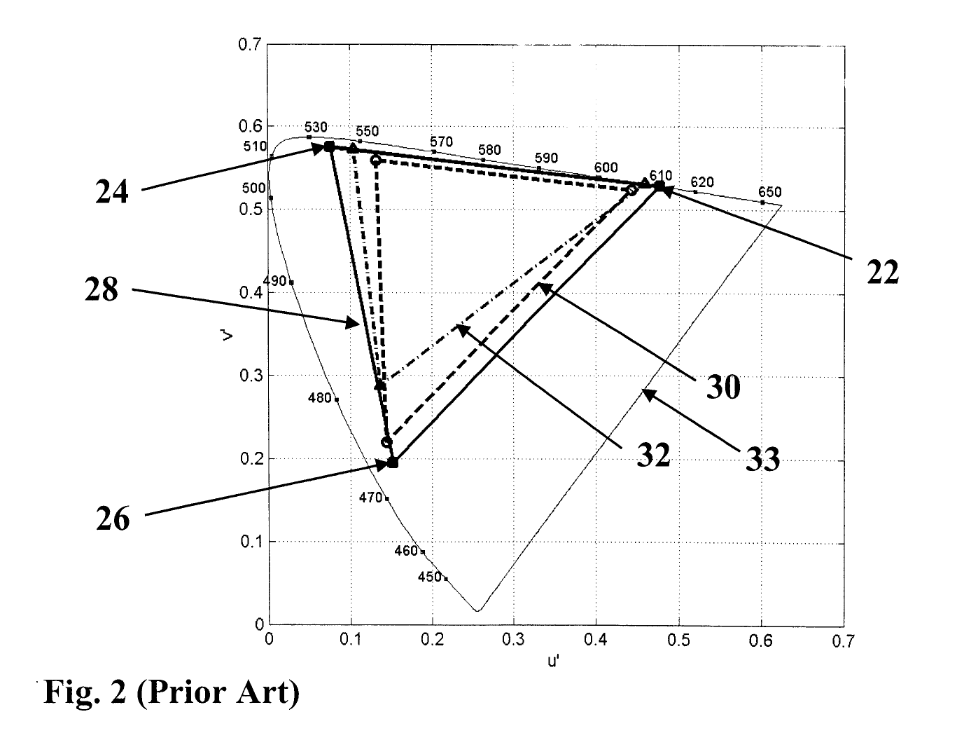

FIG. 3 shows a model QD-LED spectral emission curve known in the art;

FIG. 4 shows a CIE u′v′ chromaticity diagram illustrating the NTSC color gamut along with a hypothetical QD-LED device gamut as suggested in the prior art;

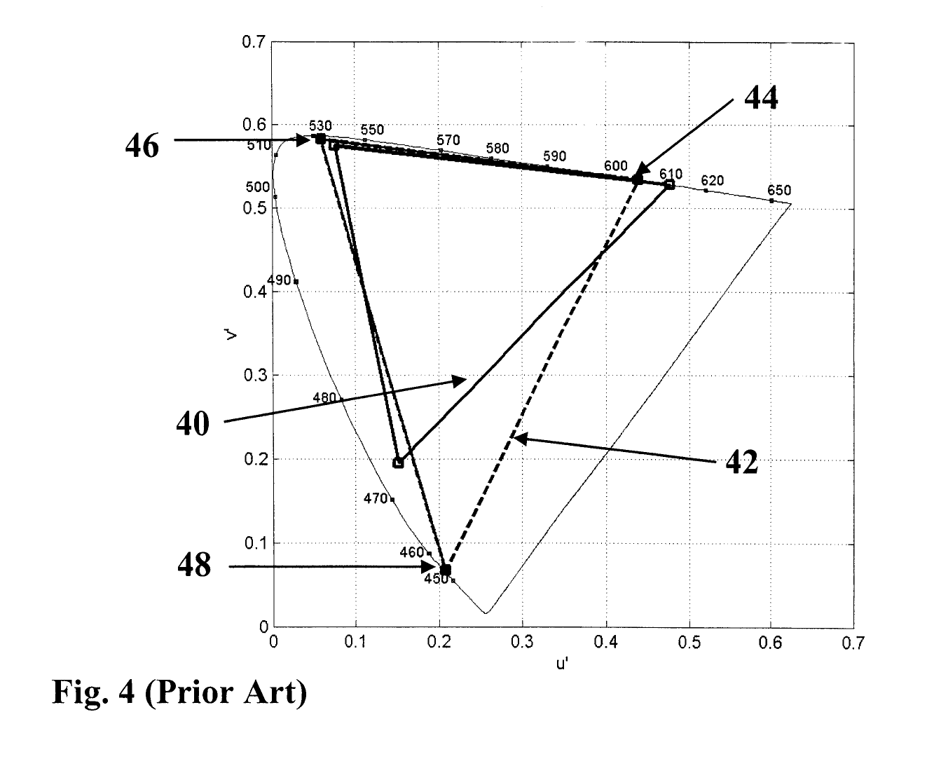

FIG. 5 shows a CIE u′v′ chromaticity diagram illustrating the u′v′ coordinates of a population of QD-LED emitters of continuously varying peak wavelength;

FIG. 6 shows a CIE u′v′ chromaticity diagram illustrating the u′v′ coordinates of three light-emitting element solutions according to an embodiment of the present invention;

FIG. 7 shows a CIE u′v′ chromaticity diagram illustrating the u′v′ coordinates of a four light-emitting element solution according to an embodiment of the present invention, along with the NTSC color gamut;

FIG. 8 shows a CIE u′v′ chromaticity diagram illustrating the u′v′ coordinates of three, four, five and six light-emitting element solutions according to an embodiment of the present invention;

FIG. 9 shows a CIE u′v′ chromaticity diagram illustrating the u′v′ coordinates of a five light-emitting element solution according to an embodiment of the present invention;

FIG. 10 shows a cross-sectional view of a device according to one embodiment of the present invention;

FIG. 11 shows a portion of a top view of a display according to another embodiment of the present invention;

FIG. 12 shows a portion of a top view of a display according to an alternative embodiment of the present invention;

FIG. 13 shows a portion of a top view of a display according to yet another embodiment of the present invention;

FIG. 14 shows a method of making a display device according to an embodiment of the present invention;

FIG. 15 shows a method of designing a display device according to one embodiment of the present invention;

FIG. 16 shows a display device according to one embodiment of the present invention; and

FIG. 17 shows a display design system according to one embodiment of the present invention.

### DETAILED DESCRIPTION OF THE INVENTION

According to the present invention, the number of light emitting elements per pixel, also called subpixels, will be chosen based on the achievable color gamut, and other engineering considerations that pertain to the application of interest. These considerations include, but are not limited to, the ability to divide the area of the pixel into multiple subregions and the attendant electrical considerations, the loss of luminous efficiency due to reduced emitting area, the geometrical design of subpixel layout, and the like. Initially, we will address the issue of choosing the proper peak wavelengths for the emitters, given the predetermined number of emitters or subpixels. As employed herein, a peak wavelength for an emitter is the wavelength having the maximum radiance for that emitter.

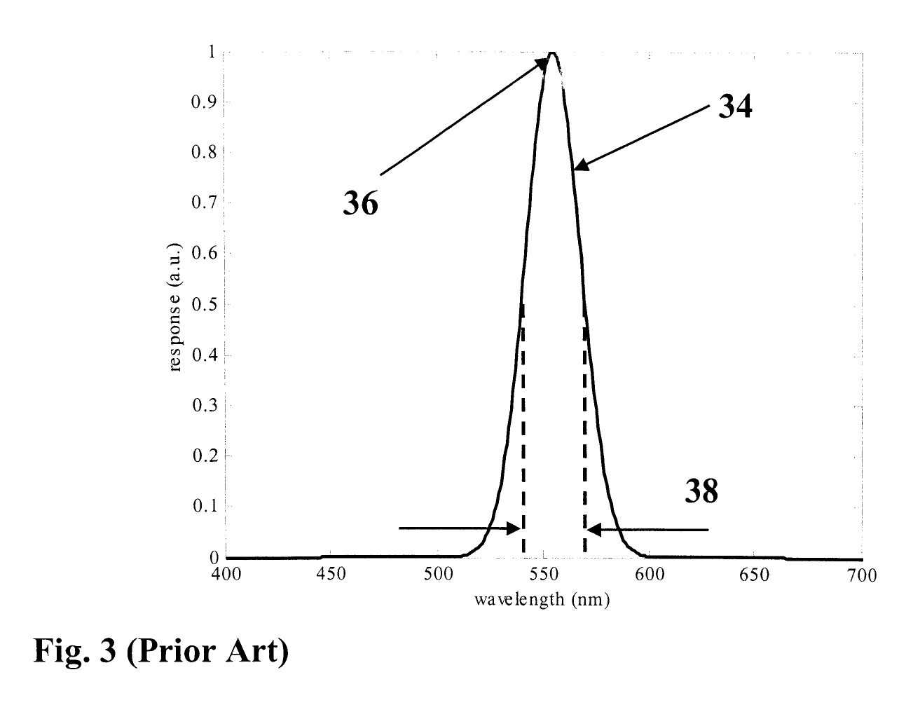

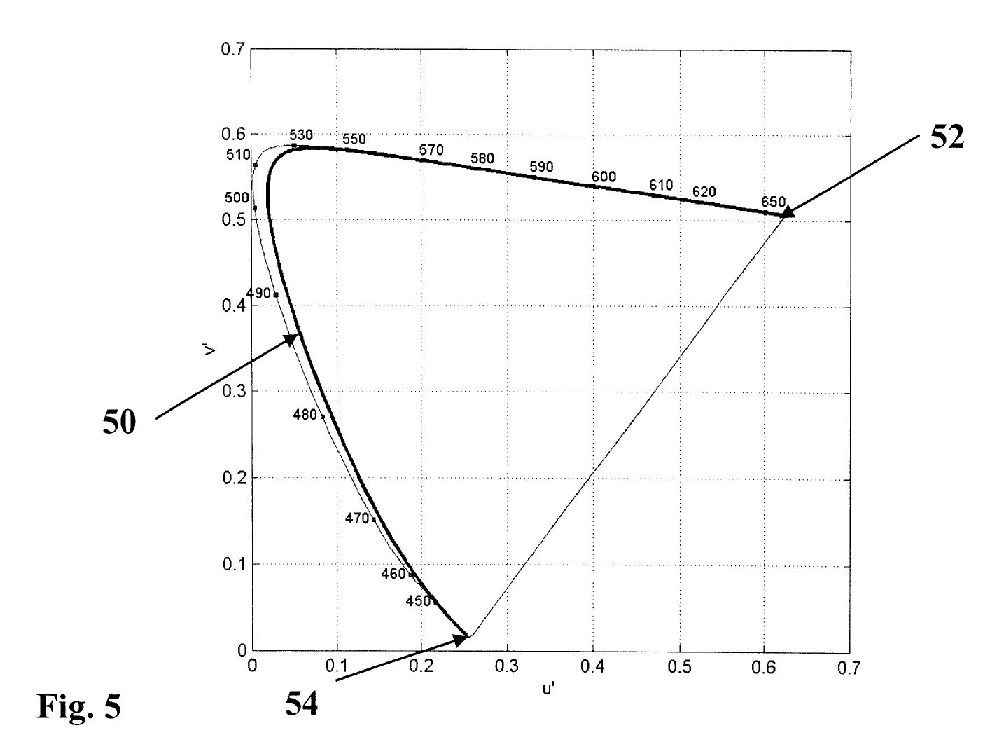

A population of QD-LED emitters with spectral emission curve shape 34 as shown in FIG. 3, if manipulated through selection of materials and nanocrystal sizes such that the peak wavelength 36 is made to vary across the visible spectrum from 400 nm to 700 nm, while controlling the size distribution such that the FWHM 38 is maintained at 30 nm, traces out a curve 50 in the u′v′ space, as shown in FIG. 5. Intuitively, we expect that for three light emitting elements per pixel, the maximum gamut area in the u′v′ space will be attained when the red and blue emitters are located near the end points 52 and 54 of the curve 50, respectively, i.e. at 700 nm and 400 nm, with the green (or green/blue) emitter located somewhere in the vicinity of the apex of the curve 50. The position of the green emitter could be inferred graphically, though this is subject to error. Note that there is no justification for assuming that either the spectrum locus or the curve 50 are symmetric, although they appear to the eye to possess an axis of symmetry roughly along the line (0.0,0.6) to (0.7,0.0). The u′v′ space, though perceptually uniform, need not possess geometrical or mathematical symmetry.

According to an embodiment of the present invention, the optimum placement of the three light emitting elements in the u′v′ space is obtained by: (1) calculating the u′v′ data for the curve 50; (2) choosing a range of peak wavelengths for each of the three emitters (here referred to as red, green and blue, their most likely hues in a three-color display); (3) choosing a wavelength increment; (4) combining the range of peak wavelengths and the wavelength increment to create three peak wavelength sets, one for each emitter; (5) combining the peak wavelength sets to form a new set of peak wavelength triplets in which all possible combinations of the emitter peak wavelengths, over the chosen ranges, and at the chosen increment, are represented; (6) computing the color gamut for each peak wavelength triplet in the u′v′ space; and (7) selecting the peak wavelength triplet that yields the maximum color gamut. The triplet so selected then represents the optimum placement of the emitters in the u′v′ space, and the preferred peak wavelengths of the associated QD-LED emitters. These steps are conveniently embodied in a computer program.

The range of peak wavelengths to be explored can be chosen to be as large as possible for each emitter, barring overlap of the emitters, so that finding the optimum is assured, or can be restricted if a priori information about the spectral emission width or shape suggests that the solutions will fall within a particular range, increasing the speed of the calculation. Similarly, the wavelength increment may be chosen based on the speed of the calculation and the desired precision of the result.

The endpoints of the peak wavelength range for the red and blue emitters pose a further problem, because the color space is quite compressed in the region approaching the purple boundary. That is, looking at the spectrum locus in FIG. 5 it is clear that the wavelengths λ<450 and λ>650 occupy much less space than the wavelengths ζ>450 and λ<650. It is common to think of the visible region as extending over the interval 400-700 nm, although examination of the CIE color matching functions x̅(λ), y̅(λ), z̅(λ) shows some response outside this interval, and for this reason color calculations are often performed over the interval 380-780 nm. The following illustrative example sheds light on this problem and on the general problem of choice of initial wavelength ranges.

Using a computer program embodiment, the above steps were implemented for a three-emitter problem, again assuming the available emitters lay on the curve 50 of FIG. 5. The range of peak wavelengths to be explored was initially set to 400-430 nm, 450-550 nm, and 670-700 nm for red, green and blue respectively. Then the range of the blue and red were varied as shown in Table 1.

TABLE 1
Results of varying input peak wavelength range according
to the present invention.

| | | | | | | | | gamut |
|---|---|---|---|---|---|---|---|---|
| | blue | blue | blue | green | red | red | red | area |
| | upper | lower | result | result | upper | lower | result | (times |
| Case | (nm) | (nm) | (nm) | (nm) | (nm) | (nm) | (nm) | 1000) |
| 1 | 400 | 430 | 400 | 515 | 670 | 700 | 700 | 1563 |
| 2 | 390 | 430 | 390 | 515 | 670 | 710 | 710 | 1569 |
| 3 | 380 | 430 | 380 | 515 | 670 | 720 | 720 | 1572 |
| 4 | 430 | 450 | 430 | 515 | 650 | 670 | 670 | 1489 |
| 5 | 450 | 470 | 450 | 515 | 630 | 650 | 650 | 1336 |
| 6 | 430 | 450 | 450 | 513 | 600 | 610 | 610 | 998 |

In general, we see that the method chooses the shortest wavelength blue and the longest wavelength red, as this obtains the maximum gamut area. In cases 1-3, the blue and red input ranges are linearly extended beyond 400 and 700, and this does result in higher gamut area, but the gains are small. In contrast, Cases 4-5 show the result of purposely constraining the red and blue peak wavelength ranges to much shorter and longer wavelengths, respectively, with more substantial changes in gamut area. Therefore constraining the blue and red peak wavelengths to 400 nm and 700 nm is a reasonable solution. In all cases, the peak wavelength range of the green was held constant, and the solution was essentially constant. The only exception was Case 6, which was included as a comparison, and was set up to result in Thornton's choices for the red and blue emitters. The resulting green wavelength is far from his suggested green, and this triplet also has the smallest color gamut of the six.

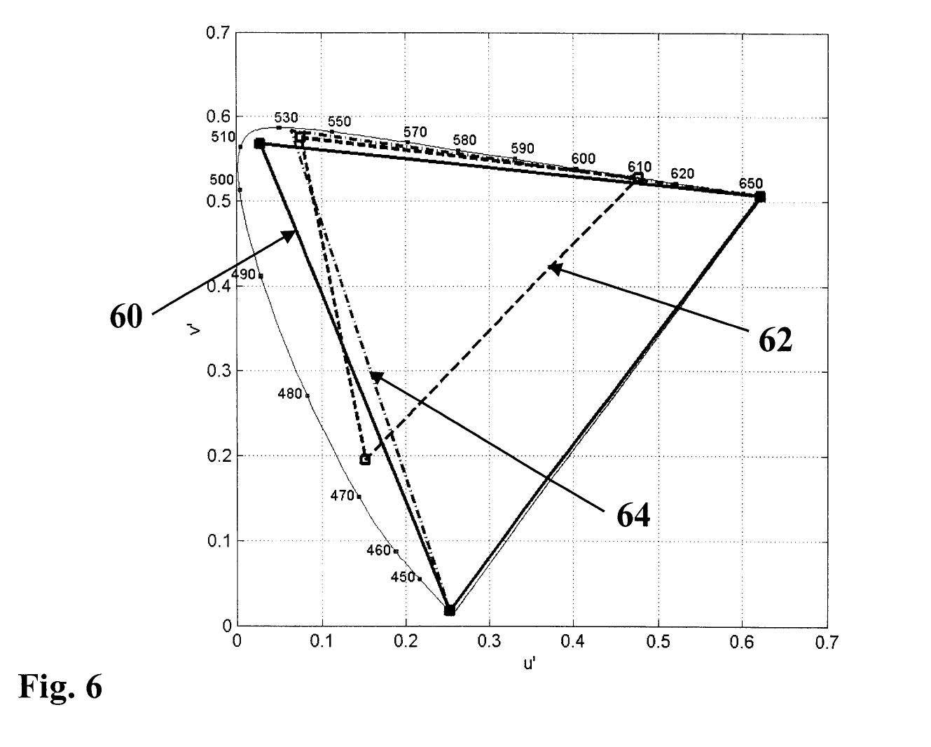

According to the present invention, the input range of peak wavelengths can also be used to perform a constrained optimization, wherein the emitters are placed so as to achieve maximum color gamut under certain additional conditions. For example, FIG. 6 shows the color gamut 60 (solid line) of the three-color solution just described, along with the gamut of the NTSC primaries 62 (dashed line). Note that for a three-color solution, the maximum possible gamut area is achieved by placing the green emitter near the apex of the spectrum locus; however this has the effect of excluding some possibly important saturated colors along the green-yellow-orange part of the locus. Of course, some green-blue or cyan colors are now made available. If it were desirable instead to preserve representation of the saturated green-yellow-orange region of the NTSC gamut, the peak wavelength range of the green emitter can be constrained on input to, for example, 530-535 nm. This results in the gamut 64, which does a better job of covering the green-yellow-orange boundary, at a penalty of around 3% in overall color gamut area.

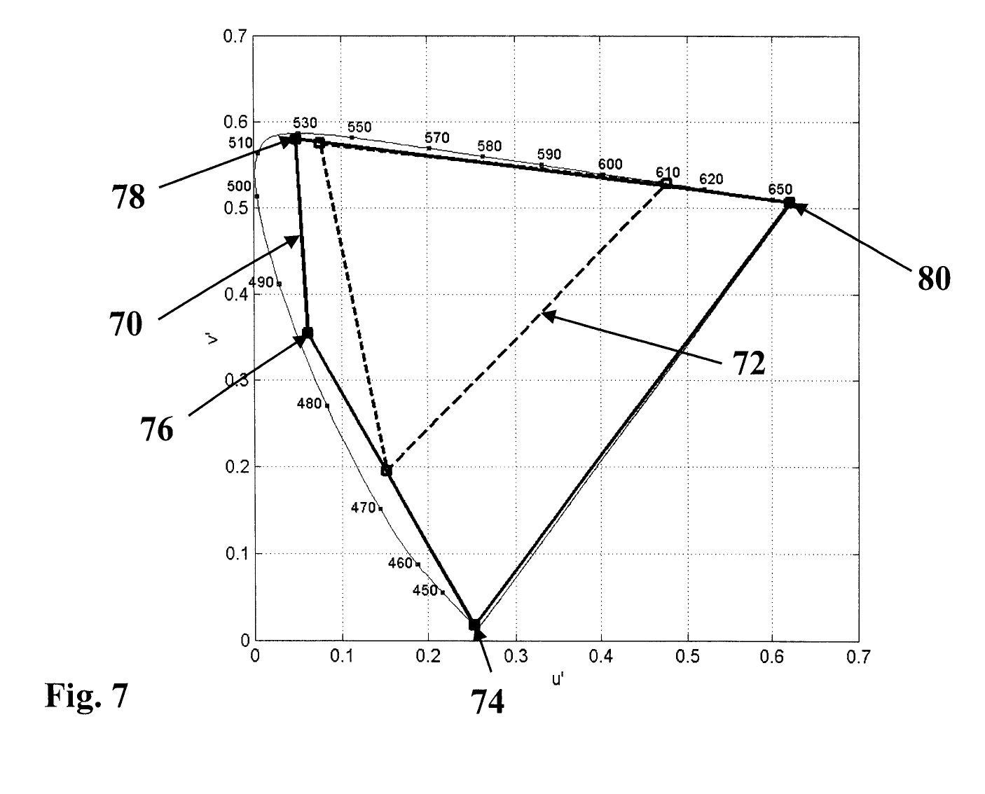

The example just described optimizes the emitters for a three light emitting element display. It is clear from the figures that a fairly large region of color space still remains uncovered. To address this shortfall, more than three light emitting elements are required, as explained in the Background. According to the present invention, the optimum placement of the four light emitting elements in the u′v′ space is obtained by: (1) using the same u′v′data for the curve 50; (2) now choosing a range of peak wavelengths for each of four emitters, two of which are expected to be red and blue, others to be determined; (3) choosing a wavelength increment; (4) combining the range of peak wavelengths and the wavelength increment to create four peak wavelength sets, one for each emitter; (5) combining the peak wavelength sets to form a new set of peak wavelength quadruplets in which all possible combinations of the emitter peak wavelengths, over the chosen ranges, and at the chosen increment, are represented; (6) computing the color gamut for each peak wavelength quadruplet in the u′v′ space; and (7) selecting the peak wavelength quadruplet that yields the maximum color gamut. This procedure is easily extended to five, six or more light emitting elements. FIG. 7 shows the optimum area solution for a four light emitting display system with color gamut 70, compared to the NTSC gamut 72. The four emitters have the u′v′ coordinates 74, 76, 78 and 80, corresponding to a deep blue, cyan, green and deep-red emitter set. With four light emitting elements the entire NTSC gamut is easily included while expanding to cover a large number of blue, red and violet colors, as well as blue-green colors, while maintaining coverage along the green-yellow-orange boundary. In an alternative embodiment of the present invention, the Recommendation ITU-R BT.709 standard (hereafter Rec. 709) may be employed instead of the NTSC standard.

Table 2 compares the optimum solutions for emitter sets ranging from 3 to 6 elements, according to the present invention. In all cases, the deep-blue and deep-red emitters have been constrained to 400 nm and 700 nm, as explained earlier.

TABLE 2
Optimum solutions for 3 to 6 light emitting element devices
according to the present invention.

| Wavelength 1 | | | | | | |
|---|---|---|---|---|---|---|
| (nm) | 2 | 3 | 4 | 5 | 6 | Gamut Area * 1000 |
| 400 | 515 | 700 | — | — | — | 1563 |
| 400 | 486 | 525 | 700 | — | — | 1731 |
| 400 | 460 | 494 | 530 | 700 | — | 1778 |
| 400 | 470 | 490 | 511 | 545 | 700 | 1821 |

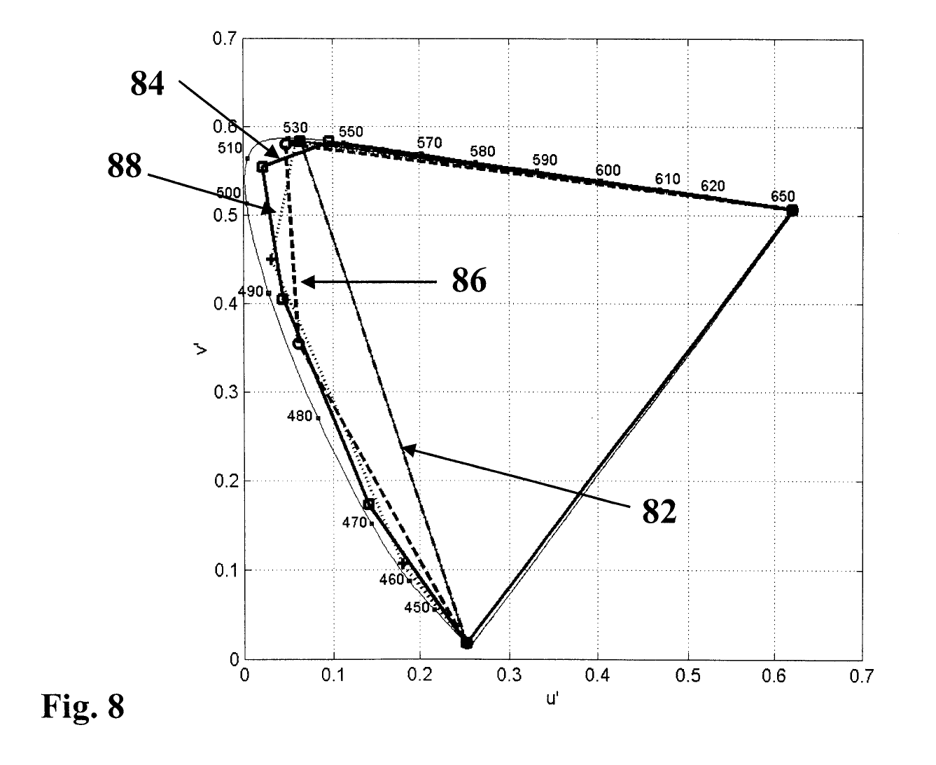

There is a large increase in gamut going from three emitters to four, a smaller increase going from four to five, and yet a smaller increase going to six. This is shown graphically in FIG. 8, where three-emitter gamut 82 is compared to four-emitter gamut 84, five-emitter gamut 86, and six-emitter gamut 88. It is important to note that according to embodiments of the present invention, the addition of emitters leads to a rearrangement of the peak wavelengths for the emitters in between the red and blue, unless constraints are applied to fix them at particular places in the color space.

Therefore according to various embodiments of the present invention, a color electroluminescent display device may have three colors, wherein the peak wavelengths of the quantum dot emitters are substantially 400 nm, 515 nm and 700 nm, or four colors, wherein the peak wavelengths of the quantum dot emitters are substantially 400 nm, 486 nm, 525 nm and 700 nm, or five colors, wherein the peak wavelengths of the quantum dot emitters are substantially 400 nm, 460 nm, 494 nm, 530 nm and 700 nm, or six colors, wherein the peak wavelengths of the quantum dot emitters are substantially 400 nm, 470 nm, 490 nm, 511 nm, 545 nm and 700 nm. According to the present invention, the word substantially refers to a wavelength range equal to the FWHM value and centered on the peak wavelength for each of the emitters.

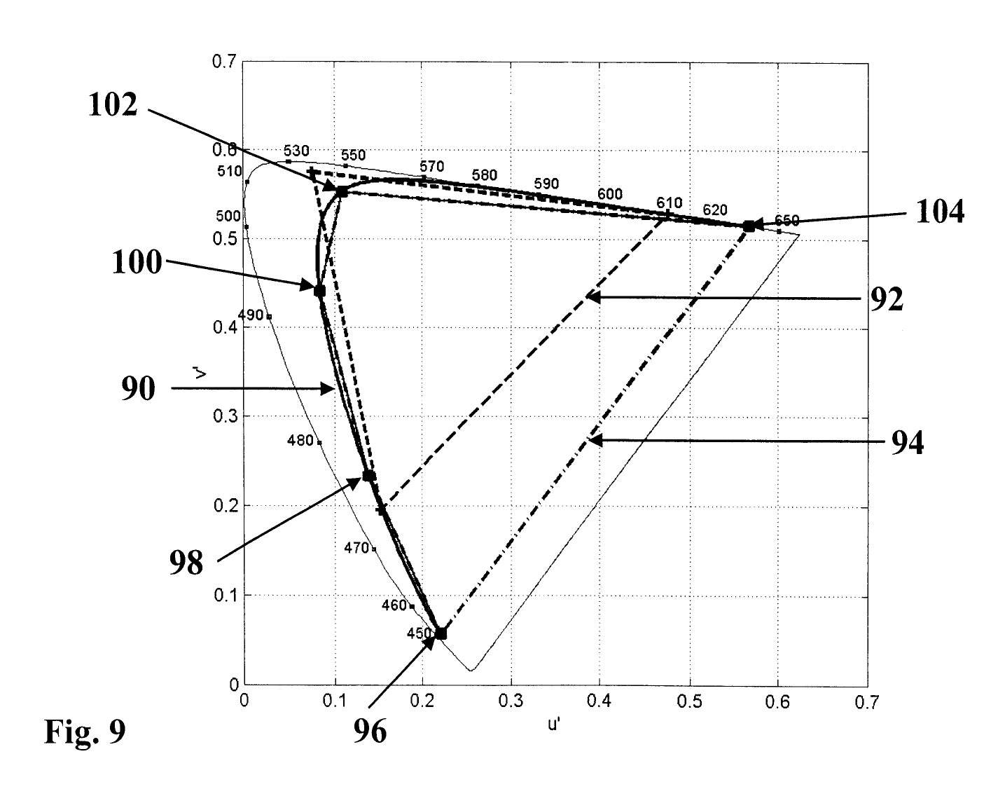

The magnitude of the FWHM will have an effect on the optimal emitter placement, as will the shape of the emitter spectral power curve in general. Returning to FIG. 3, let the FWHM 38 assume a value of 80 nm instead of 30 nm. An FWHM value of 80 nm is sufficiently broad to enable sufficiently low cost manufacturing processes for inorganic quantum dot emitters, and to provide a sufficiently narrow spectral width, and to provide a sufficiently large color gamut as compared to other flat panel devices such as OLEDs or LCDs. A minimum FWHM of 5 nm is broader than the bandwidth found in laser devices, and can be achieved in high quality manufacturing processes. An improved color gamut, at some increased manufacturing cost, can be obtained by employing an FWHM of 50 nm. A further improved color gamut may be practically achieved as demonstrated by applicant by employing quantum dots having an FWHM of 30 nm. FIG. 9 shows that if a new population of QD-LED emitters with spectral emission curve shape 34 as shown in FIG. 3 were manipulated through selection of materials and nanocrystal sizes such that the peak wavelength 36 is made to vary across the visible spectrum from 400 nm to 700 nm, while controlling the size distribution such that the FWHM 38 is maintained at 80 nm, a new curve 90 in the u′v′ space results. This is different from the curve 50 in FIG. 5 for the 30 nm case; in particular, the curve 90 has pulled sharply away from the spectrum locus from the deep blue all the way to the yellow-orange-red boundary. Not as obvious is that the endpoints 96 and 104 now fall well short of the deep blue and deep red ends of the spectrum locus. With the wider FWHM, much less gamut coverage will be possible. According to an embodiment of the present invention, the method of placing the emitters on the curve 90 proceeds as before. For example, the five-emitter solution shown in FIG. 9 has gamut 94, with emitters located at 96, 98, 100, 102 and 104. These correspond to peak wavelengths of 400, 471, 508, 550, and 700 nm, and a gamut area of 1305. Comparing to Table 2, note that the peak wavelengths are quite different from the FWHM=30 nm case, and also that the gamut area is lower than even the three-emitter solution for FWHM=30 nm. However, comparing the gamut 94 to the NTSC gamut 92, most of the latter is covered and much area in the blue-purple-red region is still gained. Hence, as illustrated by these examples, an optimum selection of emitters cannot be made by relying on the spectral emission curve shape 34 as shown in FIG. 3, and employed in the prior art. Instead a different spectral emission curve shape that takes into account the FWHM of the emitters must be employed to optimize the selection.

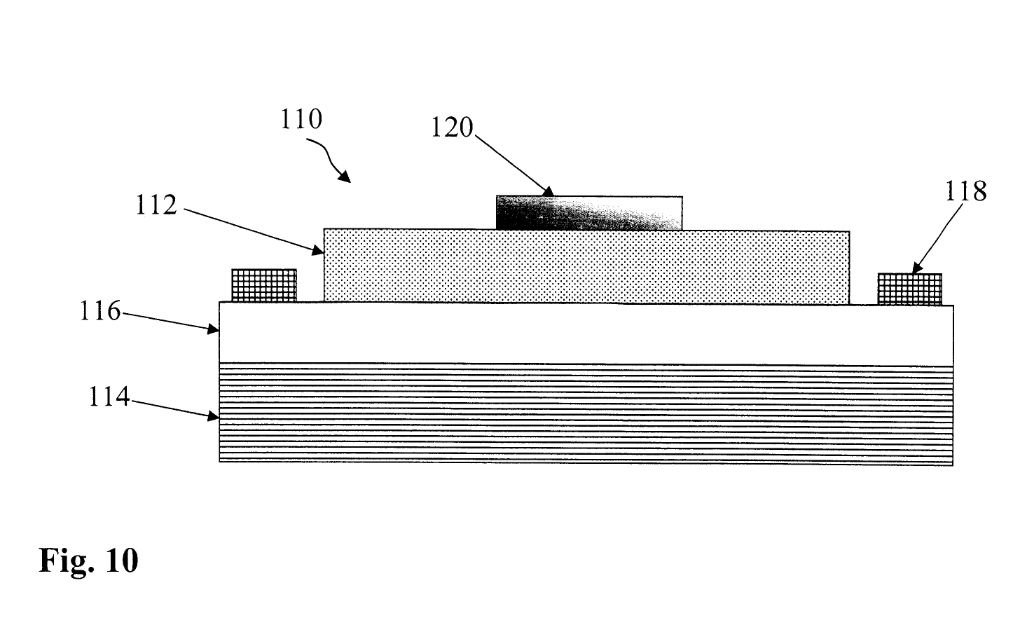

FIG. 10 shows a cross sectional view of a light-emitting element useful in practicing the present invention. As shown in this figure, the QD-LED device 110 incorporates the quantum dot inorganic light-emitting layer 112. A substrate 114 supports the deposited semiconductor and metal layers; its only requirements are that it is sufficiently rigid to enable the deposition processes and that it can withstand the thermal annealing processes (maximum temperatures of ˜285° C.). It can be transparent or opaque. Possible substrate materials are glass, silicon, metal foils, and some plastics. The next deposited material is an anode 116. For the case where the substrate 114 is p-type Si, the anode 116 needs to be deposited on the bottom surface of the substrate 114. A suitable anode metal for p-Si is Al. It can be deposited by thermal evaporation or sputtering. Following its deposition, it will preferably be annealed at ˜430° C. for 20 minutes. For all of the other substrate types named above, the anode 116 is deposited on the top surface of the substrate 114 and is comprised of a transparent conductor, such as, indium tin oxide (ITO). Sputtering or other well-known procedures in the art can deposit the ITO. The ITO is typically annealed at ˜300° C. for 1 hour to improve its transparency. Because the sheet resistance of transparent conductors, such as, ITO, are much greater than that of metals, bus metal 118 can be selectively deposited through a shadow mask using thermal evaporation or sputtering to lower the voltage drop from the contact pads to the actual device. Next is deposited the inorganic light emitting layer 112. It can be dropped or spin cast onto the transparent conductor (or Si substrate). Other deposition techniques, such as, inkjetting the colloidal quantum dot-inorganic nanoparticle mixture is also possible. Following the deposition, the inorganic light-emitting layer 112 is annealed at a preferred temperature of 270° C. for 50 minutes. Lastly, a cathode 120 metal is deposited over the inorganic light-emitting layer 112. Candidate cathode 120 metals are ones that form an ohmic contact with the material comprising the inorganic nanoparticles 112. For example, in a case where the quantum dots are formed from ZnS inorganic nanoparticles, a preferred metal is Al. It can be deposited by thermal evaporation or sputtering, followed by a thermal anneal at 285° C. for 10 minutes. Those skilled in the art can also infer that the layer composition can be inverted, such that, the cathode 120 is deposited on the substrate 114 and the anode 116 is formed on the inorganic light emitting layer 112. In this configuration, when the substrate 114 is formed from Si, the substrate 114 is n-type Si.

Although not shown in FIG. 10, a p-type transport layer and an n-type transport layer may be added to the device to surround the inorganic light-emitting layer 112. As is well known in the art, LED strictures typically contain doped n- and p-type transport layers. They serve a few different purposes. Forming ohmic contacts to semiconductors is simpler if the semiconductors are doped. Since the emitter layer is typically intrinsic or lightly doped, it is much simpler to make ohmic contacts to the doped transport layers. As a result of surface plasmon effects, having metal layers adjacent to emitter layers results in a loss of emitter efficiency. Consequently, it is advantageous to space the emitter layers from the metal contacts by sufficiently thick (at least 150 nm) transport layers. Finally, not only do the transport layers inject electron and holes into the emitter layer, but, by proper choice of materials, they can prevent the leakage of the carriers back out of the emitter layer. For example, if the inorganic quantum dots in the light-emitting layer 112 were composed of ZnS_{0.5}Se_{0.5} and the transport layers were composed of ZnS, then the electrons and holes would be confined to the emitter layer by the ZnS potential barrier. Suitable materials for the p-type transport layer include II-VI and III-V semiconductors. Typical II-VI semiconductors are ZnSe, ZnS, or ZnTe. Only ZnTe is naturally p-type, while ZnSe and ZnS are n-type. To get sufficiently high p-type conductivity, additional p-type dopants should be added to all three materials. For the case of II-VI p-type transport layers, possible candidate dopants are lithium and nitrogen. For example, it has been shown in the literature that Li₃N can be diffused into ZnSe at ˜350° C. to create p-type ZnSe, with resistivities as low as 0.4 ohm-cm.

Suitable materials for the n-type transport layer include II-VI and III-V semiconductors. Typical II-VI semiconductors are ZnSe or ZnS. As for the p-type transport layers, to get sufficiently high n-type conductivity, additional n-type dopants should be added to the semiconductors. For the case of II-VI n-type transport layers, possible candidate dopants are the Type III dopants of Al, In, or Ga. As is well known in the art, these dopants can be added to the layer either by ion implantation (followed by an anneal) or by a diffusion process. A more preferred route is to add the dopant in-situ during the chemical synthesis of the nanoparticle. Taking the example of ZnSe particles formed in a hexadecylamine (HDA)/TOPO coordinating solvent, the Zn source is diethylzinc in hexane and the Se source is Se powder dissolved in TOP (forms TOPSe). If the ZnSe were to be doped with Al, then a corresponding percentage (a few percent relative to the diethylzinc concentration) of trimethylaluminum in hexane would be added to the syringe containing TOP, TOPSe, and diethylzinc. In-situ doping processes like these have been successfully demonstrated when growing thin films by a chemical bath deposition. It should be noted the diode could also operate with only a p-type transport layer or an n-type transport layer added to the structure.

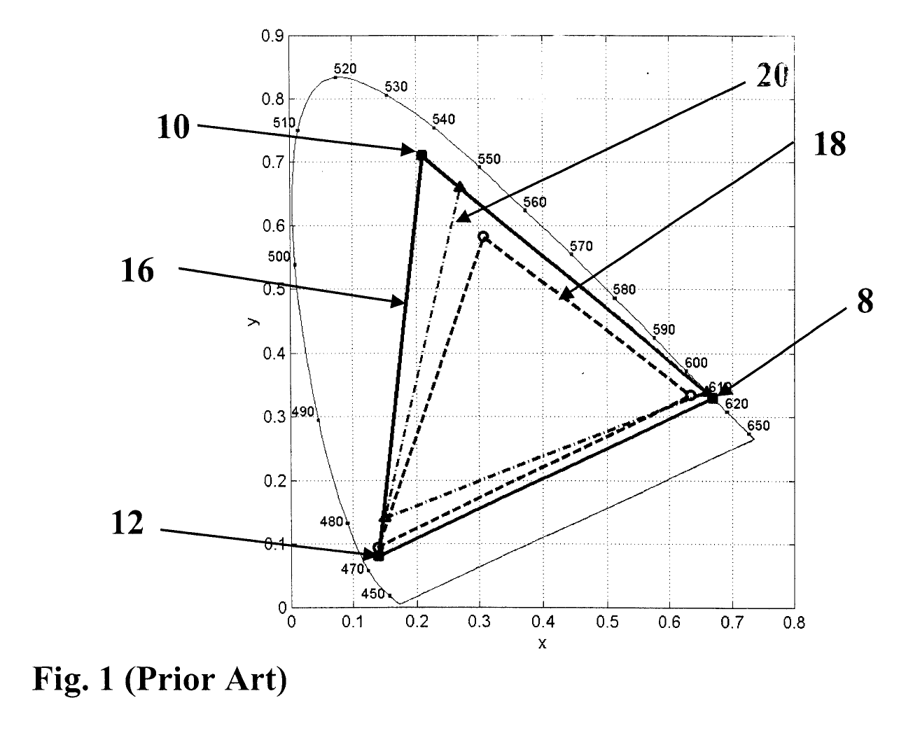

In one embodiment, the electro-luminescent display device of the present invention is a four-color display and the array of light emitting elements includes at least red, green, blue and cyan light emitting elements, as depicted previously in FIG. 7. Within the four-color display each of the light emitting elements has a light-emitting layer comprised of quantum dots and will typically have a distribution of sizes. These light-emitting elements will typically be patterned beside each other to form a full-color display, a portion 121 of which is depicted in FIG. 1l. As shown in this figure, such a full-color display device will have an array of light-emitting elements that includes the cyan light-emitting elements 122, 124, as well as additional light-emitting elements for emitting red light 126, 128, green light 130, 132, and blue light 134, 136. While the portion 121 of the full-color display as shown in FIG. 8 applies active matrix circuitry to drive the light-emitting elements of the display device, the display device may also apply passive-matrix circuitry as is well known in the art.

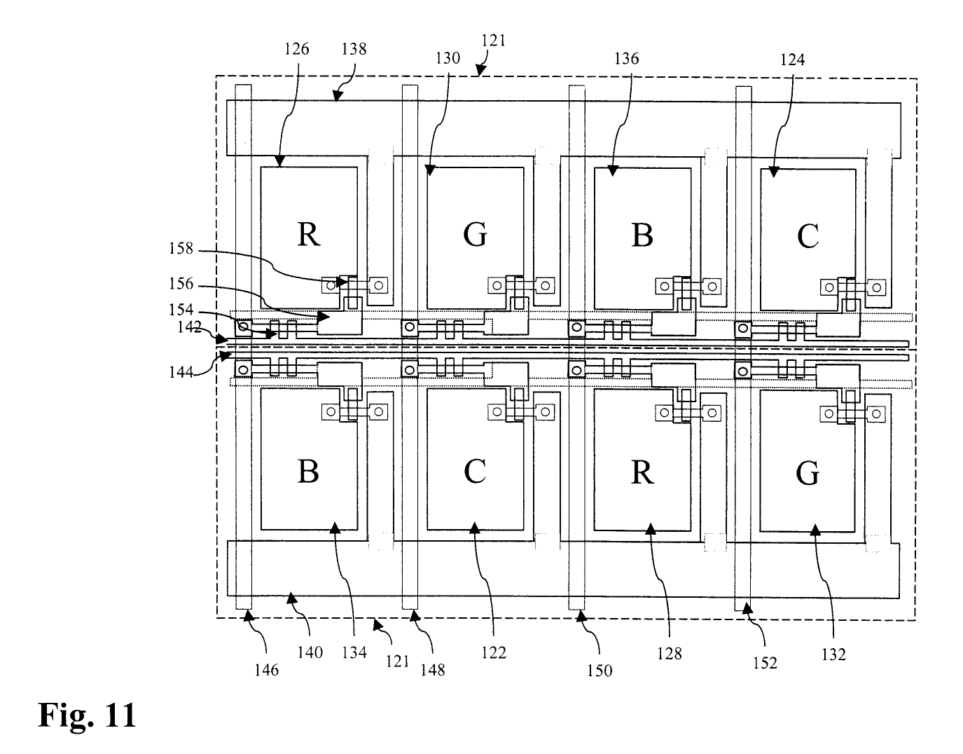

As shown in FIG. 11, active matrix circuitry for driving a device of the present invention will typically include power lines 138, 140 for providing current to the light-emitting elements, select lines 142, 144 for selecting a row of circuits, drive lines 146, 148, 150, 152 for providing a voltage to control each of the circuits, select TFTs 154 for allowing the voltage for a drive line 146, 148, 150, 152 to be provided only to the light-emitting elements in a column that receive a select signal on a select line 142 or 144, a capacitor 156 for maintaining a voltage level between each line refresh and a power TFT 158 for controlling the flow of current from the power lines 138, 140 to one of the electrodes for each light-emitting element.

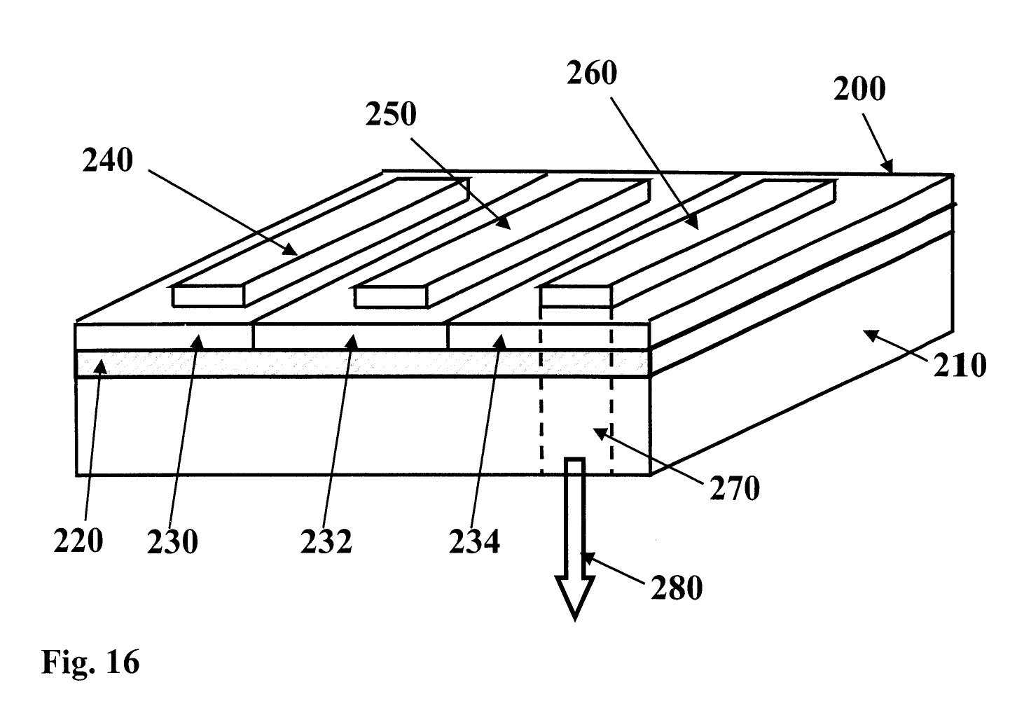

A color electroluminescent display device of the present invention comprises one or more pixels, one pixel 200 of which is shown for example in FIG. 16. Each pixel has a plurality of light emitting elements defined by electrodes 240, 250 and 260, each element emitting light of a different wavelength. In this example, there are three light emitting elements per pixel. There are also light emitting layers 230, 232 and 234 for each of the different light emitting elements that include an inorganic light-emitter selected from a substantially continually variable wavelength set of inorganic light-emitters as described above, and wherein the different inorganic light emitters emit different wavelengths of light, the different wavelengths of light providing the maximum color gamut area within a perceptually uniform two-dimensional color space. A transparent lower, unpatterned electrode layer 220 is provided to complete an electrical circuit between electrodes 240, 250 and 260 and the electrode 220. The layers are formed on the substrate 210, which may be made of glass or other suitable material as previously described. When a voltage (not shown) is applied between upper electrodes (i.e. cathodes) 240, 250, 260 and lower electrode (i.e. anode) 220, light is emitted through the substrate. In particular, when voltage is applied, patterned cathode 260 emits light 280 through the region 270, thereby defining the emitting area of the element as seen from below the substrate.

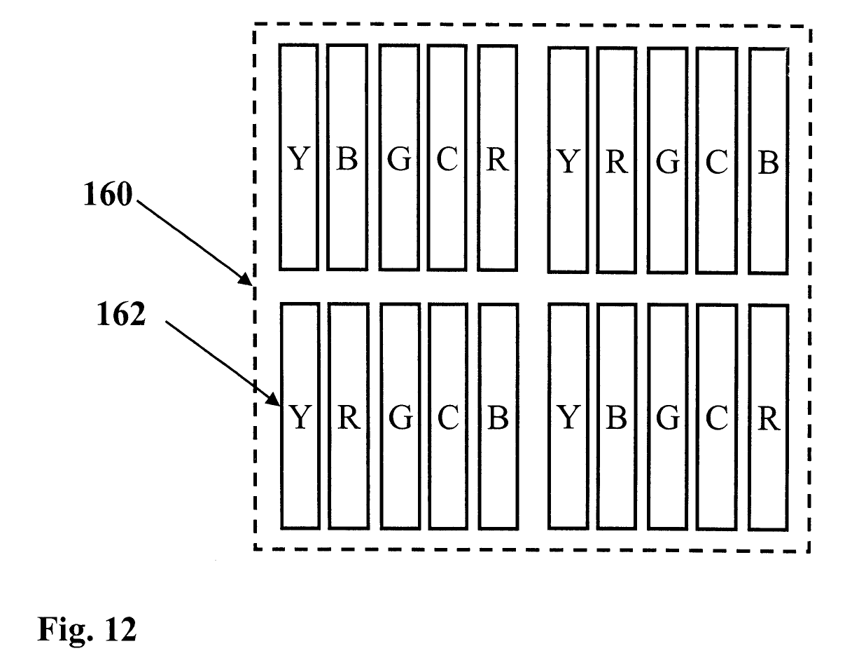

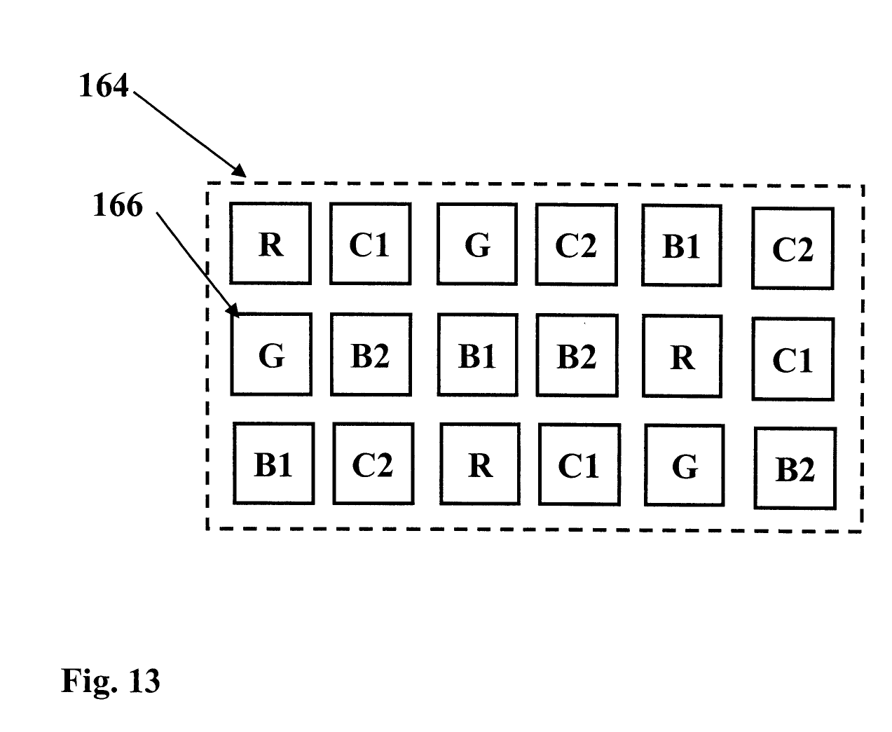

It will be appreciated that many geometrical layouts are possible for the light emitting elements in cases of three, four five and six colors per pixel, within the spirit and scope of the invention. Such variations in layout may include alternation in the position of light emitting elements from pixel to pixel, and/or subsampling of certain colors, that is the use of a higher proportion of light emitting elements of some colors compared to other colors. These concepts are discussed in US application 2005/0270444A1 by Miller et. al., which is incorporated herein by reference. One well-known possibility for four light emitting elements has been shown in FIG. 11. FIG. 12 shows one possibility for a five emitter layout, taken from US 2005/0270444A1 by Miller et. al. FIG. 12 shows a portion of a display 160 wherein light emitting elements 162 are grouped into pixels, each pixel containing five of the elements. In this case the elements are blue, yellow, green, cyan and red in color, though the exact colors are not critical to the layout. In this case the positions of the red and blue pixels alternate between adjacent pixels. FIG. 13 shows one possibility for a six-emitter layout. Here a portion of a display 164 is shown with light emitting elements 166 grouped into three pixels, each containing six light emitting elements. The colors are red, green and what are classified as two types of blue and cyan, as suggested by the results in Table 2 and the gamut 84 of FIG. 8. In this layout the emitters are made to rotate positions every third pixel to break up high frequency periodic patterns.

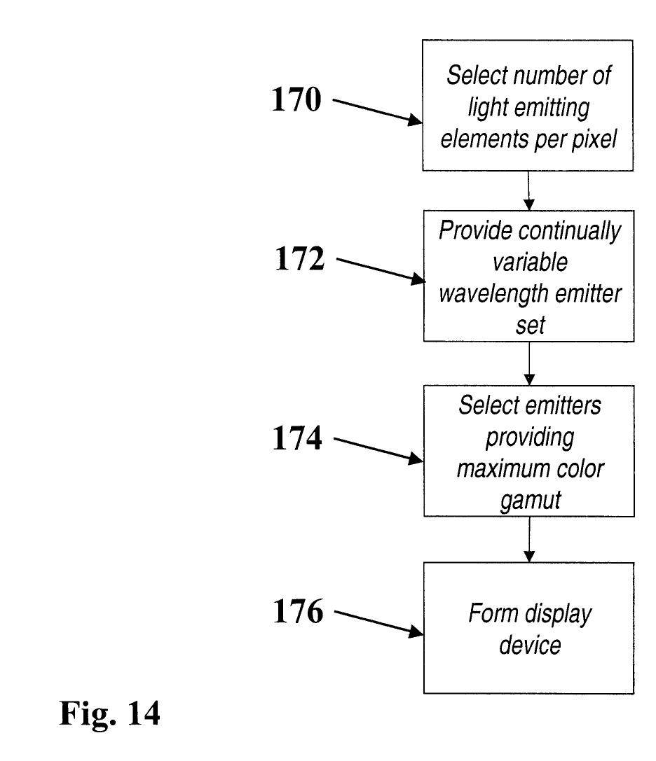

A method of making a display device in accordance with the principles of the invention is shown in FIG. 14, and comprises the steps of: 170, determining a number of light emitting elements per pixel; 172, providing a substantially continually variable wavelength set of inorganic light-emitters having a spectral width; 174, selecting the number determined in 170 of different inorganic light emitters that emit light at the same determined number of different wavelengths and provide the maximum color gamut area within a perceptually uniform two-dimensional color space; and 176, forming the color electroluminescent display device having the same determined number of light emitting elements per pixel, wherein the light emitting elements in each pixel employ the same determined number of different inorganic light emitters. As previously discussed, the selection 170 of the number of light emitting elements per pixel is driven by the desire to maximize the color gamut, but also by other engineering considerations. For example, the electronic design rules for supporting circuitry may require a certain amount of area on the display to be devoted to power and data delivery lines, thus reducing the emissive area of the display. To achieve the specified display luminance, the emissive elements must then be driven at a proportionally higher current density, which may have deleterious effects on the lifetime of the emissive elements. Greater numbers of elements per pixel may increase the manufacturing complexity, leading to greater unit costs. Such considerations, in addition to color gamut specifications, guide the choice of the number of elements. The continually variable wavelength emitter set 172 is provided by a population of QD-LED emitters with spectral emission curve shape 34 as shown in FIG. 3, manipulated through selection of materials and nanocrystal sizes such that the peak wavelength 36 is made to vary across the visible spectrum, while controlling the size distribution such that the desired FWHM 38 is maintained. The selection 174 of the emitters providing maximum color gamut has been described above. The display device may be formed in 176 using the light emitting elements, materials and driver circuitry described above.

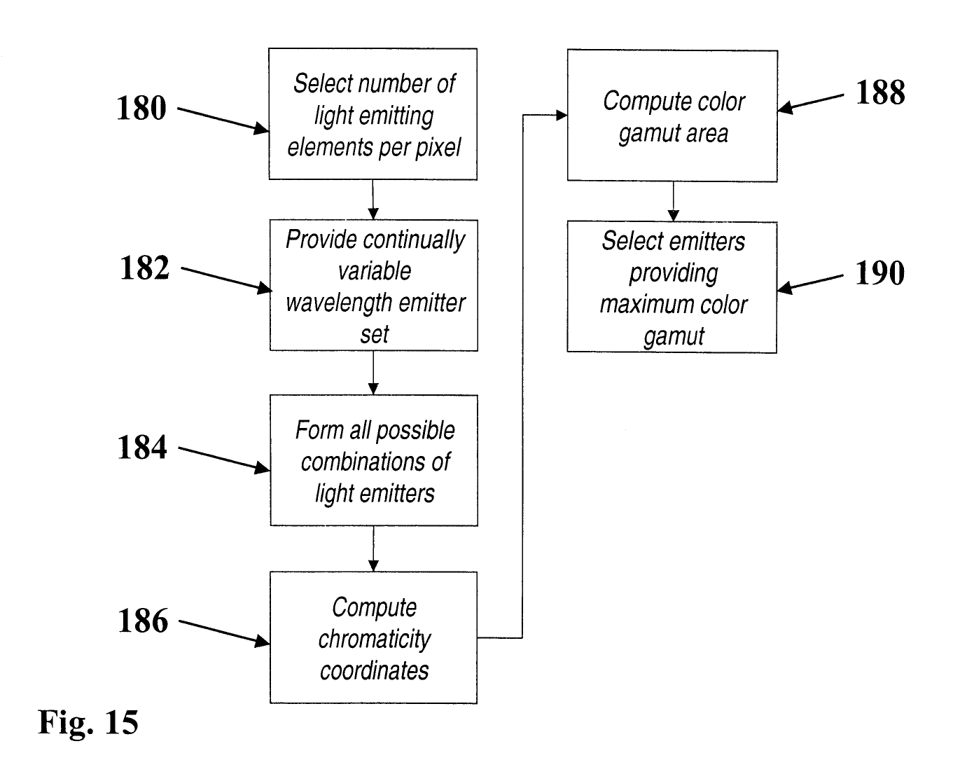

In another embodiment of the present invention, a method of designing a color electroluminescent display device is shown in FIG. 15, and comprises the steps of: 180, selecting the number n of light emitting elements per pixel; 182, providing a substantially continually variable wavelength set of inorganic light-emitters; 184, forming all possible combinations of inorganic light-emitters from the continually variable wavelength set, wherein each combination is of the same number as the determined number of light emitting elements per pixel; 186, computing the chromaticity coordinates of the combinations of inorganic light-emitters in a perceptually uniform two-dimensional color space; 188, computing the color gamut area for the combinations of inorganic light emitters in the perceptually uniform two-dimensional color space; and 190 selecting the combination of inorganic light emitters that provide the maximum color gamut area within the perceptually uniform two-dimensional color space. Steps 180 and 182 are the same as steps 170 and 172 of FIG. 14, and have already been described. Step 184 refers to the process whereby a range of peak wavelengths is chosen for each of the n emitters a wavelength increment is chosen, the range of peak wavelengths and the wavelength increment are combined to create n peak wavelength sets, where n is 3, 4, 5, 6, etc. Continuing in step 184, the peak wavelength sets are then combined to form a new set in which all possible combinations of groups-of-n of emitter peak wavelengths, over the chosen ranges, and at the chosen increment, are represented. In step 186, the u′v′ chromaticity coordinates of each group-of-n emitters are computed, so that in step 188 the color gamut area associated with each group-of-n emitters can then be computed. In step 190, the set of group-of-n emitters providing maximum color gamut is then selected.

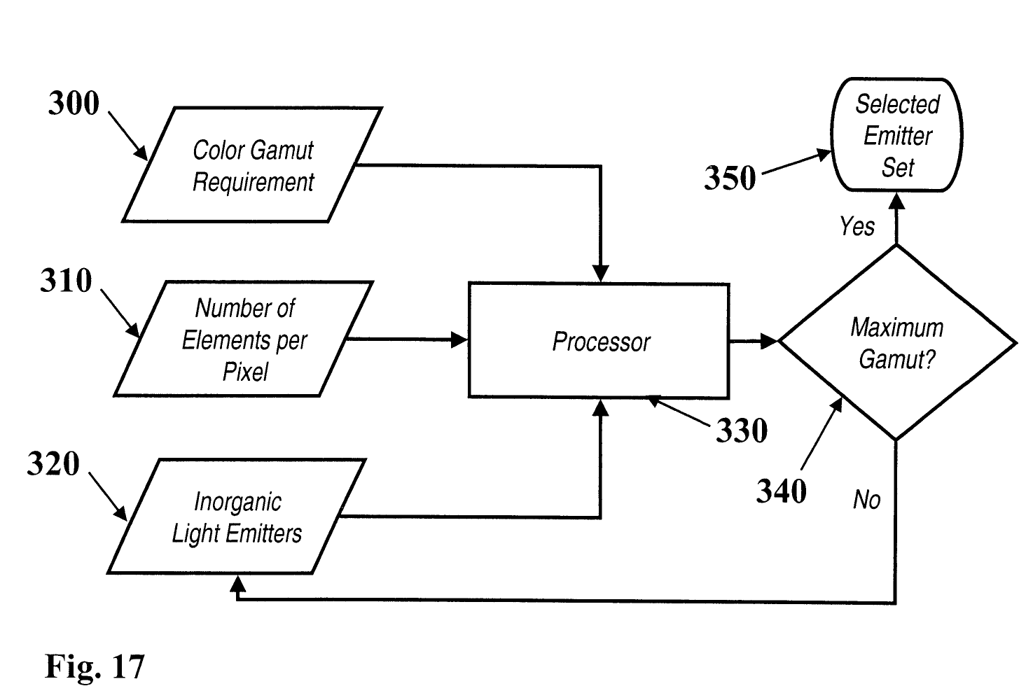

In another embodiment of the present invention, FIG. 17 shows a display design system, comprising: 300, a selected color gamut requirement; 310, a number of light emitting elements per pixel; 320, a substantially continually variable wavelength set of inorganic light-emitters; and 330, a processor that is programmed to select the set of inorganic light emitters, wherein different inorganic light emitters emit different frequencies of light, the different wavelength of light providing the maximum color gamut area within a perceptually uniform two-dimensional color space. The number 310 of light emitting elements per pixel, and the continually variable wavelength set of inorganic light-emitters 320 have been described previously. Here it is the descriptive data associated with the emitters 320, along with the number of elements 310 and the color gamut requirements 300 of the display application that are the inputs to a processor 330 that selects an emitter set 350 for use in the designed display. The processor 330 executes the step of examining all possible combinations of groups-of-n of emitters, described earlier with reference to FIG. 15. The processor examines each combination to determine 340 if the maximum gamut has been reached; if it has, the combination producing maximum gamut is the selected emitter set 350. If not, the processor returns to the next member of the emitter set 320 and continues until the maximum gamut is reached.

The invention has been described in detail with particular reference to certain preferred embodiments thereof, but it will be understood that variations and modifications can be effected within the spirit and scope of the invention.

### PARTS LIST

8 NTSC red primary
10 NTSC green primary
12 NTSC blue primary
16 NTSC color gamut
18 LCD color gamut
20 OLED color gamut
22 NTSC red primary
24 NTSC green primary
26 NTSC blue primary
28 NTSC color gamut
30 LCD color gamut
32 OLED color gamut
33 blue-purple-red boundary
34 spectral emission curve
36 maximum of spectral emission curve
38 full-width half-maximum of spectral emission curve
40 NTSC color gamut
42 QD-LED color gamut
44 suggested red primary
46 suggested green primary
48 suggested blue primary
50 locus of QD-LED emitters
52 red terminus of QD-LED emitters
54 blue terminus of QD-LED emitters
60 color gamut for three QD-LED emitters
62 NTSC color gamut
64 color gamut for three different QD-LED emitters
70 color gamut for four QD-LED emitters
72 NTSC color gamut
74 deep-blue emitter
76 blue-green emitter
78 green emitter
80 deep-red emitter
82 three-emitter color gamut
84 four-emitter color gamut
86 five-emitter color gamut
88 six-emitter color gamut
90 locus of QD-LED emitters
92 NTSC color gamut
94 QD-LED color gamut
96 deep-blue emitter
98 blue emitter
100 blue-green emitter
102 green emitter
104 deep-red emitter
110 QD-LED device
112 quantum dot inorganic light-emitting layer
114 substrate
116 anode
118 bus
120 cathode
121 portion of display
122 cyan light emitting element
124 cyan light emitting element
126 red light emitting element
128 red light emitting element
130 green light emitting element
132 green light emitting element
134 blue light emitting element
136 blue light emitting element
138 power line
140 power line
142 select line
144 select line
146 drive line
148 drive line
150 drive line
152 drive line
154 select TFT
156 capacitor
158 power TFT
160 portion of display
162 light emitting elements
164 portion of display
166 light emitting elements
170 selection step
172 provision step
174 selection step
176 formation step
180 selection step
182 provision step
184 formation step
186 computation step
188 computation step
190 selection step
200 portion of display
210 substrate
220 anode
230 light emitting layer
232 light emitting layer
234 light emitting layer
240 cathode
250 cathode
260 cathode
270 light emitting region
280 emitted light
300 color gamut requirement data
310 number of elements per pixel data
320 inorganic light emitter data
330 processor
340 decision
350 selected emitter set

1. A method of making a color electroluminescent display device; comprising the steps of:
a. determining a number of light emitting elements per pixel;
b. providing a substantially continually variable wavelength set of inorganic light-emitters having a spectral width;
c. selecting the number determined in step (a) of different inorganic light emitters that emit light at the same determined number of different wavelengths and provide the maximum color gamut area within a perceptually uniform two-dimensional color space; and
d. forming the color electroluminescent display device having the same determined number of light emitting elements per pixel, wherein the light emitting elements in each pixel employ the same determined number of different inorganic light emitters.

2. The method claimed in claim 1, wherein the substantially continually variable wavelength set of inorganic light-emitters has a full width half maximum spectral bandwidth greater than five nanometers and less than eighty nanometers.

3. The method claimed in claim 1, wherein the substantially continually variable wavelength set of inorganic light-emitters has a full width half maximum spectral bandwidth greater than five nanometers and less than fifty nanometers.

4. The method claimed in claim 1, wherein the inorganic light-emitters are quantum dots.

5. A method of designing a color electroluminescent display device; comprising the steps of:
a. determining a number of light emitting elements per pixel;
b. providing a substantially continually variable wavelength set of inorganic light-emitters having a spectral width;
c. forming all possible combinations of inorganic light-emitters from the continually variable wavelength set, wherein each combination has the same determined number of light emitting elements per pixel;
d. computing the coordinates of the combinations of inorganic light-emitters in a perceptually uniform two-dimensional color space;
e. computing the color gamut area for the combinations of inorganic light emitters in the perceptually uniform two-dimensional color space;
f. selecting the combination of inorganic light emitters that provide the maximum color gamut area within the perceptually uniform two-dimensional color space.

6. The method claimed in claim 5, wherein the substantially continually variable wavelength set of inorganic light-emitters has a full width half maximum spectral bandwidth greater than five nanometers and less than eighty nanometers.

7. The method claimed in claim 5, wherein the substantially continually variable wavelength set of inorganic light-emitters has a full width half maximum spectral bandwidth greater than five nanometers and less than fifty nanometers.

8. The method claimed in claim 3, wherein the inorganic light-emitters are quantum dots.

9. A color electroluminescent display device, comprising:
a. one or more pixels, each pixel having a plurality of light emitting elements, each light emitting element emitting light of a different wavelength;
b. a light emitting layer for each of the different light emitting elements that includes an inorganic light-emitter selected from a substantially continually variable wavelength set of inorganic light-emitters; and
c. wherein different inorganic light emitters emit different wavelengths of light, the different wavelengths of light providing the maximum color gamut area within a perceptually uniform two-dimensional color space.

10. The color electroluminescent display device as claimed in claim 9, wherein:
a. the light emitting elements are four or more in number, three of the elements being red, green and blue; and
b. the four or more light emitting elements have a spectral bandwidth less than or equal to eighty nanometers at full width half maximum.

11. The color electroluminescent display device as claimed in claim 9, wherein:
a. the light emitting elements are four or more in number, three of the elements being red, green and blue; and
b. the four or more light emitting elements have a spectral bandwidth less than or equal to fifty nanometers at full width half maximum.

12. The color electroluminescent display device as claimed in claim 9, wherein at least one light-emitting layer contains quantum dots.

13. The color electroluminescent display device as claimed in claim 9 having three colors, and wherein the peak wavelengths of the quantum dot emitters are substantially 400 nm, 515 nm and 700 nm.

14. The color electroluminescent display device as claimed in claim 9 having four colors, and wherein the peak wavelengths of the quantum dot emitters are substantially 400 nm, 486 nm, 525 nm and 700 nm.

15. The color electroluminescent display device as claimed in claim 9 having five colors, and wherein the peak wavelengths of the quantum dot emitters are substantially 400 nm, 460 nm, 494 nm, 530 nm and 700 nm.

16. The color electroluminescent display device as in claim 9 having six colors, and wherein the peak wavelengths of the quantum dot emitters are substantially 400 nm, 470 nm, 490 nm, 511 nm, 545 nm and 700 nm.

17. The color electroluminescent display device of claim 9, further comprising one or more light emitting elements in each pixel wherein the light emitting element is chosen to minimize the power usage of the display device.

18. The color electroluminescent display device of claim 9, further comprising one or more light emitting elements in each pixel wherein the light emitting elements emit light of a wavelength set that includes a predetermined color gamut area.

19. The color electroluminescent display device of claim 18, wherein the area of the color gamut is at least 100% of the area defined by the chromaticity coordinates for emitters defined according to the NTSC standard or Rec.709 standard.

20. A display design system, comprising:
a. a selected color gamut requirement;
b. a number of light emitting elements per pixel;
c. a substantially continually variable wavelength set of inorganic light-emitters; and
d. a processor that is programmed to select the set of inorganic light emitters wherein different inorganic light emitters emit different frequencies of light, the different wavelength of light providing the maximum color gamut area within a perceptually uniform two-dimensional color space.
